(19) United States
(12) Patent Application Publication
(10) Pub. No.: US 2024/0341027 A1
(43) Pub. Date: Oct. 10, 2024

(54) HIGHLY INTEGRATED POWER ELECTRONICS AND METHODS OF MANUFACTURING THE SAME

(71) Applicant: Toyota Motor Engineering & Manufacturing North America, Inc., Plano, TX (US)

(72) Inventors: Feng Zhou, Ann Arbor, MI (US); Tianzhu Fan, Houston, TX (US); Ercan Mehmet Dede, Ann Arbor, MI (US)

(21) Appl. No.: 18/130,718

(22) Filed: Apr. 4, 2023

(51) Int. Cl. H05K 1/02; H05K 7/20

(52) U.S. Cl. CPC H05K 1/0203; H05K 7/20254; H05K 7/20263; H05K 7/20272; H05K 7/20927; B33Y 10/00

(57) ABSTRACT

A method of fabricating or manufacturing a highly integrated power electronics (IPEs) embedded printed circuit board (PCB)—cold plate assembly includes bonding a cold plate substrate onto a first side of a power device—substrate assembly, bonding a multi-layer PCB onto a second side of the power device—substrate assembly, and bonding a cold plate manifold onto the multi-layer PCB and forming a cold plate in thermal communication a power device of the power device—substrate assembly. The multi-layer PCB can be 3D printed onto the second side of the power device—substrate assembly and bonding of the cold plate manifold to the multi-layer PCB can be reinforced with mechanical fasteners.

### TECHNICAL FIELD

The present disclosure relates to integrated power electronics, and particularly to printed circuit boards with power devices embedded therein.

### BACKGROUND

Printed circuit boards (PCBs) are typically used for mechanical support and electrical connection of electronic components using conductive pathways of copper sheets laminated onto a non-conductive substrate. And multi-layer PCBs provide higher capacity and/or density of electronic components in a smaller footprint by incorporating two or more layers in electrical communication within one or more power devices. However, the design and/or manufacture of multilayer PCBs and their electrical communication with the one or more power devices can be difficult.

The present disclosure addresses issues related to the manufacture of multi-layer PCBs and other issues related to multi-layer PCBs.

### SUMMARY

This section provides a general summary of the disclosure and is not a comprehensive disclosure of its full scope or all of its features.

In one form of the present disclosure, a method of fabricating or manufacturing a highly integrated power electronics (IPEs) embedded printed circuit board (PCB)—cold plate assembly includes bonding a cold plate substrate onto a first side of a power device—substrate assembly, bonding a multi-layer PCB onto a second side of the power device—substrate assembly, and bonding a cold plate manifold onto the multi-layer PCB and forming a cold plate in thermal communication with the power device—substrate assembly.

In another form of the present disclosure, a method includes bonding a cold plate substrate onto a first side of a power device—substrate assembly, 3D printing a multi-layer PCB onto a second side of the power device—substrate assembly oppositely disposed from the first side, bonding a cold plate manifold onto the multi-layer PCB and forming a cold plate in thermal communication with the power device—substrate assembly, and installing a plurality of mechanical fasteners to reinforce the cold plate manifold bonded to the multi-layer PCB.

In still another form of the present disclosure, a method includes bonding a cold plate substrate onto a first side of a power device—substrate assembly, 3D printing a multi-layer printed circuit board (PCB) onto a second side of the power device—substrate assembly, bonding a polymer cold plate manifold onto the multi-layer PCB and forming, in combination with the cold plate substrate, a cold plate, and installing a plurality of mechanical fasteners to reinforce the bonding of the polymer cold plate manifold bonded to the multi-layer PCB.

Further areas of applicability and various methods of enhancing the above technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1 shows a side cross-sectional view of a highly integrated power electronics embedded PCB—cold plate assembly according to the teachings of the present disclosure;

FIG. 2A shows a perspective view of a multi-layer PCB for the highly integrated power electronics embedded PCB—cold plate assembly in FIG. 1;

FIG. 2B shows a perspective for a power layer of the multi-layer PCB in FIG. 2A:

FIG. 3 shows a side view and block diagram of a three dimensional (3D) printing system for manufacturing multi-layer PCBs according to one form of the present disclosure;

FIG. 4A shows a side cross-sectional view of a pair of cold plate substrates to be bonded to a pair power of power device—substrate assemblies according to the teachings of the present disclosure;

FIG. 4B shows the pair of cold plate substrates bonded to the pair or power device—substrate assemblies in FIG. 4A;

FIG. 4C shows a side cross-sectional view of a multi-layer PCB to be bonded to the pair of power device—substrate assemblies in FIG. 4B;

FIG. 4D shows the multi-layer PCB bonded to the pair of power device—substrate assemblies in FIG. 4C;

FIG. 4E shows a side cross-sectional view of a cold plate manifold bonded to multi-layer PCB in FIG. 4D;

FIG. 4F shows an inlet tube, an outlet tube, and mechanical fasteners to be assembled with the cold plate manifold bonded to multi-layer PCB in FIG. 2E to form the highly integrated power electronics embedded PCB—cold plate assembly in FIG. 1; and

FIG. 5 shows a flow chart for a method of manufacturing a highly integrated power electronics embedded PCB—cold plate assembly according to still another form of the present disclosure.

It should be noted that the figures set forth herein are intended to exemplify the general characteristics of the methods, devices, and systems among those of the present technology, for the purpose of the description of certain aspects. The figures may not precisely reflect the characteristics of any given aspect and are not necessarily intended to define or limit specific forms or variations within the scope of this technology.

### DETAILED DESCRIPTION

The present disclosure provides highly integrated power electronics embedded PCB—cold plate assemblies and methods of manufacturing highly integrated power electronics (IPEs) embedded PCB—cold plate assemblies. As used herein, the phrases “integrated power electronics embedded PCB” and “highly integrated power electronics embedded PCB” refer to a single multi-layer PCB module or unit with two or more power semiconductor devices (also referred to herein simply as “power device” or “power devices”), control/drive/protection electronic circuitry, and/or passive components, embedded therein and/or attached to. Also, as used herein, the phrase “power device” refers to a semiconductor device used as a switch or rectifier in power electronics. The highly IPEs embedded PCB—cold plate assemblies each include a cold plate with an IPEs embedded PCB bonded to and in thermal communication with the cold plate. The cold plate can be fluid cooled, i.e., a cooling fluid can flow through the cold plate, such that temperatures of the one or more power devices during operation remain below a predefined temperature.

The methods of manufacturing highly IPEs embedded PCB—cold plate assemblies include bonding cold plate substrates to a first side of two or more power device—substrate assemblies, bonding a multi-layer PCB to a second side of the two or more power device—substrate assemblies, and bonding a cold plate manifold to the multi-layer PCB such that a cold plate is formed and is in thermal communication with the two or more power device—substrate assemblies. In some variations the multi-layer PCB is 3D printed onto the two or more power device—substrate assemblies. In at least one variation, the cold plate substrate includes a bonding substrate and fins, porous material, mesh-structured, machined and/or cast heat sinks integral with or bonded to the bonding substrate. And in such variations, the cold plate manifold encapsulates the fins, porous material, mesh-structured, machined and/or cast heat sinks such that a fluid chamber of the cold plate includes or contains the fins, porous material, mesh-structured, machined and/or cast heat sinks. As used herein, the phrase “integral with” refers to at least two components or at least two sections or portions of one component formed from a single piece of material. For example, in variations where the cold plate substrate includes the bonding substrate and the fins integral with the bonding substrate, the bonding substrate and the fins can be machined from a single piece of material or formed from a single casting.

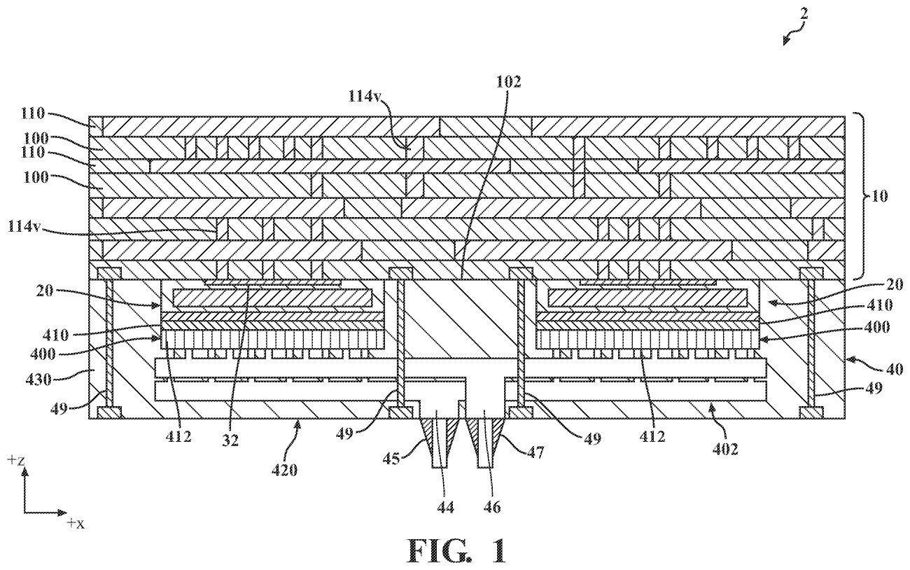

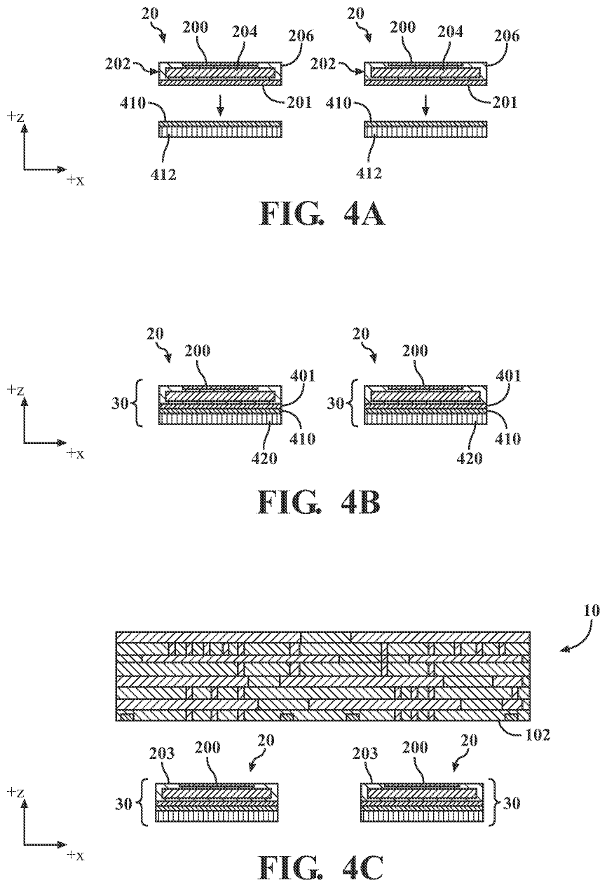

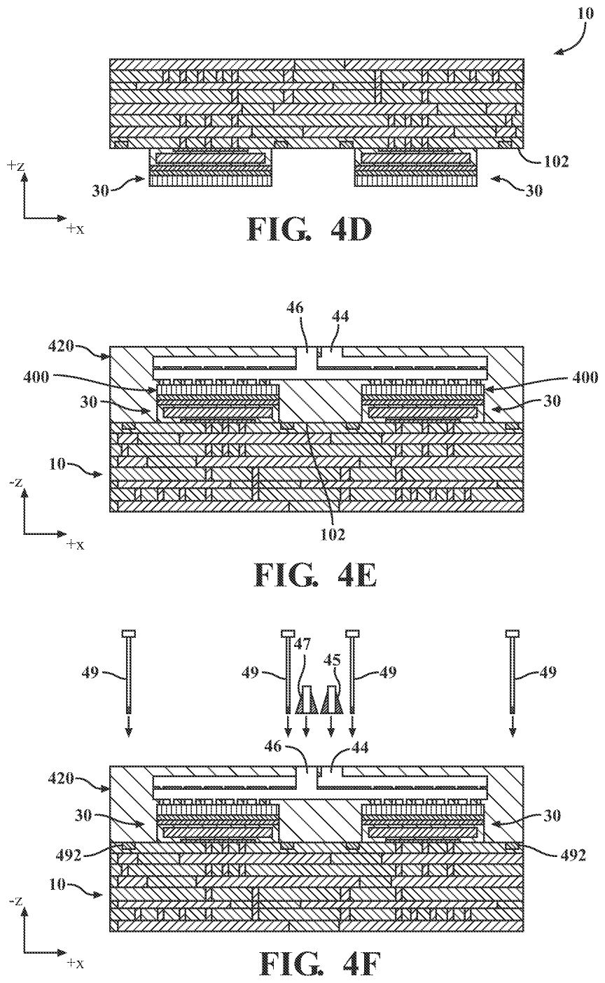

Referring to FIG. 1, a side cross-sectional view of a highly IPEs embedded PCB—cold plate assembly 2 according to one form of the present disclosure is shown. The IPEs embedded PCB—cold plate assembly 2 includes a multi-layer PCB 10, two or more power device—substrate assemblies 20, and a cold plate 40. The multi-layer PCB 10 includes a plurality of dielectric layers 100, a plurality of power layers 110, and conductive vias 114v that provide electrical communication or pathways between adjacent power layers 110. The one or more power device—substrate assemblies 20 include a power device 200 (e.g., a MOSFET power device) attached or bonded to a substrate 202 (FIG. 4A). For example, in some variations the power device—substrate assembly 20 includes a power device 200 bonded to a copper-graphite substrate 202 with a graphite core 204 embedded within a shell 206 of copper (FIG. 4A). And in such variations, the power device 200 can be bonded to the copper shell 206, e.g., via silver sintering.

The cold plate 40 includes a fluid chamber 400 encapsulated within or between a cold plate substrate 410 and a cold plate manifold 420 that is bonded to a lower (−z direction) surface 102 of the multi-layer PCB 10. In some variations, one or more mechanical fasteners 49 can be included and used to enhance bonding of the cold plate manifold 420 to a lower surface 102 of the multi-layer PCB 10 and/or provide reinforcement to the cold plate manifold 420. The cold plate 40 includes an inlet 44 and an outlet 46 such that a cooling fluid (not shown) can flow through the fluid chamber 400. In some variations, an inlet tube 45 is attached to the inlet 44 and an outlet tube 47 is attached to the outlet 46. And in at least one variation, fins, porous material, mesh-structured, machined and/or cast heat sinks 412 are disposed within the fluid chamber 400 and enhance heat transfer from the power devices 200 to the cooling fluid flowing through the fluid chamber 400 during use and/or operation of the highly IPEs embedded PCB—substrate assembly 2.

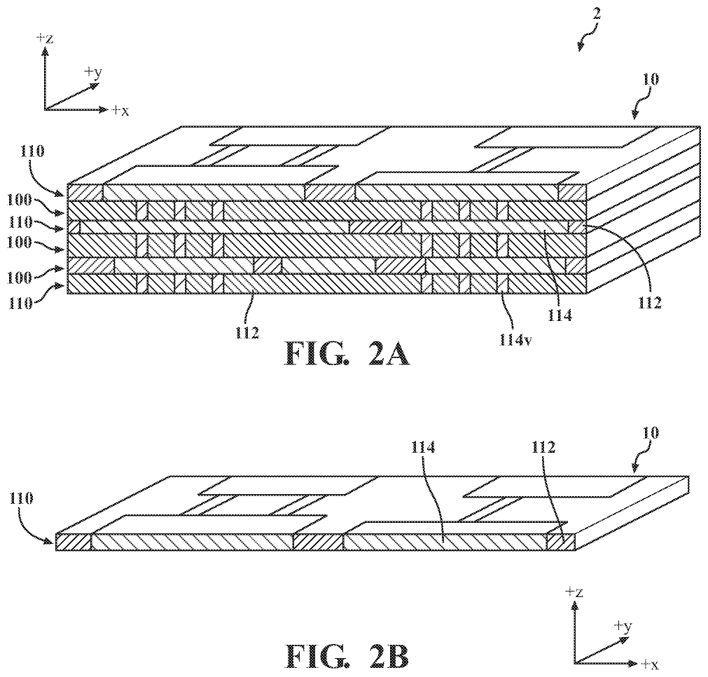

Regarding the multi-layer PCB 10, and with reference to FIGS. 2A-2B, a perspective cross-sectional view of the multi-layer PCB 10 is shown in FIG. 2A and an isolated perspective cross-sectional view of one of the power layers 110 is shown in FIG. 2B. The power layers 110 include a dielectric material 112 and a conductive material 114. The dielectric layers 100 include the dielectric material 112 and conductive vias 114v that provide electrical communication or pathways between adjacent power layers 110. Stated differently, the power layers 110 include conductive (e.g., copper) patterns and the dielectric layers 100 include conductive (e.g., copper) pathways that connect the patterns of conductive material 114 such that the multi-layer PCB 10 functions and/or operates as desired.

In some variations, the dielectric layers 100 and/or the power layers 110 are formed from a glass reinforced epoxy laminate dielectric material (e.g., FR-4), or other dielectric material, with the conductive material 114 embedded therein. In other variations, the power layers 110 and/or the dielectric layers 100 are 3D printed using a dielectric material ink to form the dielectric material 112, with the conductive material 114 embedded therein. And in at least one variation, the conductive material 114 is also 3D printed with a conductive material ink. Non limiting examples of dielectric material inks are inks that include UV-curable dielectric materials such as UV-curable acrylated monomers selected from one or more of an acrylate epoxy, an acrylate polyester, an acrylate urethane, and an acrylate silicone, among others. And non-limiting examples of conductive material inks are inks that include silver nanoparticles and/or graphene nanosheets, among others.

The dielectric layers 100 and the power layers 110 have a predefined average thickness (z-direction). For example, in some variations, the predefined average thickness is between about 50 micrometers (μm) and about 250 μm, for example, between about 75 μm and about 200 μm. And in at least one variation, the predefined thickness is between about 75 μm and about 150 μm, for example, between about 80 μm and about 120 μm.

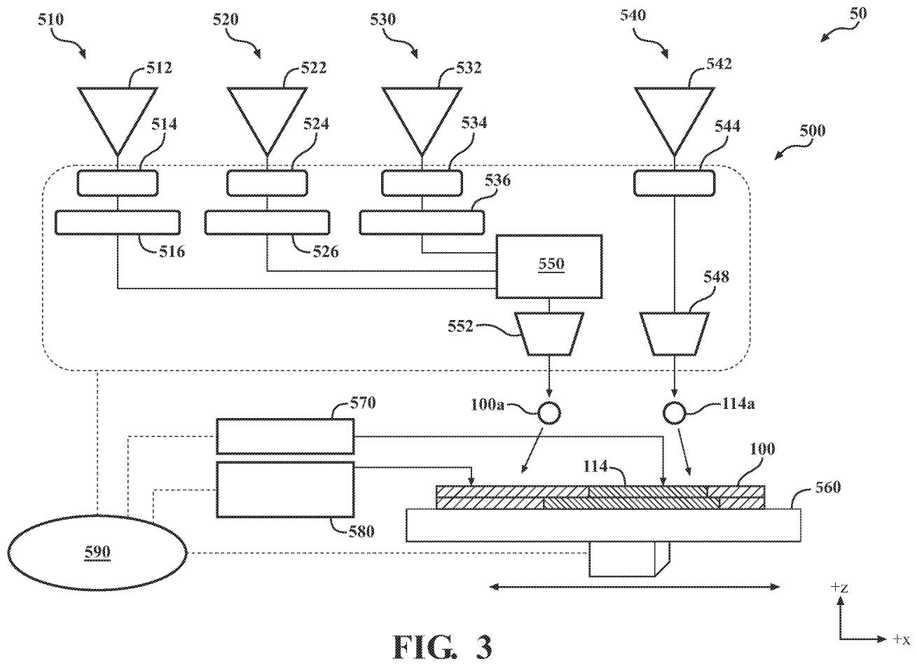

As mentioned above, in some variations the dielectric layers 100 and the power layers 110 are formed by 3D printing. For example, and with reference to FIG. 3, a 3D printing system 50 for the manufacture of a multi-layer PCB (e.g., multi-layer PCB 10) according to one form of the present disclosure is shown. The 3D printing system 50 includes a 3D printer 500 (e.g., an inkjet 3D printer), a platform 560, and a controller 590. In some variations, the platform 560 and/or the controller 590 are part of the 3D printer 500, while in other variations, the platform 560 and/or the controller 590 are components that are separate from but in communication with the 3D printer 500 such that the controller 590 can command the 3D printer 500 and the platform 560 to execute predefined operations, movements, etc., as described below.

The 3D printer 500 includes a reservoir 510 (e.g., a bin or a hopper) for a UV-curable dielectric material 512 (with or without additives such as photo-initiators), a reservoir 520 for a low CTE filler 522, a reservoir 540 for a conductive material 542, and a mixer 550 in fluid communication with reservoirs 520, 540. In some variations, the 3D printer 500 also includes a reservoir 530 in fluid communication with the mixer 550, the reservoir 530 being for a surfactant 532 that enhances mixing of the UV-curable dielectric material 512 and the low CTE filler 522 in the mixer 550. And in at least one variation, the reservoir 520 includes a mixture of the low CTE filler 522 and a solvent and/or dispersing agent that enhances flow of the low CTE filler 522 from the reservoir 520 to the mixer 550 and/or enhances mixing of the low CTE filler 522 with the UV-curable dielectric material 512 in the mixer 550.

The UV-curable dielectric material 512 with or without additives such as photo-initiators) can be any UV-curable dielectric material, including without limitation a UV-curable acrylated monomer selected from one or more of an acrylate epoxy, an acrylate polyester, an acrylate urethane, and an acrylate silicone, among others. Also, the low CTE filler 522 can be any filler having a CTE less than the CTE of the UV-curable dielectric material 512 after being cured, including without limitation a ceramic filler and/or a cellulose nanofiber filler, among others. For example, the ceramic filler can include nanoparticles selected from one or more of aluminum nitride, silicon nitride, cordierite, and aluminum oxide, among others. In some variations, a surfactant and/or a dispersing agent can be included in the low CTE filler 522 such that enhanced dispersion with reduced “clumping” or segregation of a ceramic filler and/or cellulose nanofiber filler within the solvent mentioned above is provided.

In at least one variation, the 3D printer 500 includes: a pump 514 and/or a flow controller 516 for controlling flow of the UV-curable dielectric material 512 from the reservoir 510 to the mixer 550; a pump 524 and/or a flow controller 526 for controlling flow of the low CTE filler 522 from the reservoir 520 to the mixer 550; and/or a pump 534 and/or a flow controller 536 for controlling flow of the surfactant 532 from the reservoir 530 to the mixer 550.

The mixer 550 is configured to desirably mix the UV-curable dielectric material 512, the low CTE filler 522, and the surfactant 532 (when included) into a UV-curable dielectric ink 100a that includes the UV-curable dielectric material 512 and flows from a first nozzle 552 to form a dielectric layer 100. In addition, the 3D printer 500 can include a pump 544 and/or a flow controller (not shown) for controlling flow of a conductive ink 114a containing the conductive material 542 from the reservoir 540 to a second nozzle 548 to form a pattern of a conductive material 114. In some variations, the conductive ink 114a includes silver nanoparticles and/or graphene nanosheets. And as noted above, the term “nozzle” as used herein refers to a nozzle for direct writing of material onto a surface (also known as direct-ink-writing (DIW)) or a printer head having an array of nozzles in which ink droplets are deposited on a surface (also known as 3D inkjet printing). Accordingly, in some variations the 3D printer 500, and other 3D printers disclosed herein, is a DIW 3D printer, while in other variations, the 3D printer 500, and other 3D printers disclosed herein, is a 3D inkjet printer.

It should be understood that the platform 560 and/or the nozzles 552, 548 can have three degrees of freedom, i.e., can move in the x, y, and z-directions shown in the figure. For example, in some variations the platform 560 moves in the x and y directions while the nozzles 552, 548 print a given layer of a multi-layer PCB on a surface of the platform 560 (also referred to hereafter simply as “on the platform” or “onto the platform”), and then after 3D printing of the given layer is complete, the platform 560 moves in the-z direction by a predefined distance (e.g., a distance equal to a thickness of the just formed layer) such that the nozzles 552, 548 can print another layer of the multi-layer PCB.

Still referring to FIG. 3, in some variations the 3D printing system 50 includes a thermal curing device 570 (e.g., a heater) configured to thermally cure the conductive ink 114a printed on the platform 560 or a previously formed layer and/or a UV curing device 580 (e.g., a UV light source) configured to UV cure the UV-curable dielectric ink 100a printed on the platform 560 or a previously formed layer. In at least one variation, the UV curing device 580 includes a thermal curing function such that the UV-curable dielectric ink 100a is UV and thermally cured before and/or during 3D printing of a subsequent layer of the multi-layer PCB.

As noted above, the 3D printing system 50 includes a controller 590. In some variations, the controller 590 is configured to command the pump 514, the flow controller 516, the pump 524, the flow controller 526, the pump 534, and/or the flow controller 536, such that a desired amount of UV-curable dielectric material 512, low CTE filler 522, and surfactant 532 (when included) is provided to the mixer 550. And in such variations, the mixer 550 is configured to mix the UV-curable dielectric material 512, low CTE filler 522, and surfactant 532 (when included) such that a desired UV-curable dielectric ink 100a flows and exits from the first nozzle 552 at a desired flow rate. It should be understood that the UV-curable dielectric ink 100a is deposited (printed) on the platform 560 or other surface (e.g., a previously formed layer) at predefined voxels of a given layer of the multi-layer PCB. In addition, the controller 590 can be configured to command the mixer 550 and/or the first nozzle 552 such that the desired UV-curable dielectric ink 100a flows and exits from the first nozzle 552 at a desired flow rate. Similarly, in some variations the controller 590 is configured to command the pump 544, a corresponding flow controller (not shown), and/or the second nozzle 548 such that a desired amount of conductive ink 114a flows and exits the second nozzle 548 at desired flow rate, and is deposited (printed) on the platform 560 or a previously formed layer at predefined voxels.

During operation of the 3D printing system 50, the controller 590 is provided information (e.g., from a user interface, look-up table, etc.) for the manufacture of a multi-layer PCB (referred to hereafter as the multi-layer PCB 10). The multi-layer PCB 10 has a plurality of layers, and each layer can include a predefined electronic circuity with predefined regions, areas, layers, and/or traces of conductive material combined with, or absence of, predefined regions, areas, layers, and/or traces of dielectric material. Stated differently, a given layer of the multi-layer PCB 10 has a predefined design or layout of conductive material and dielectric material. In addition, the controller 590 commands the various components described above such that each dielectric layer 100 and each power layer 110 of the multi-layer PCB 10 is 3D printed and cured until the entire multi-layer PCB 10 is formed. And while FIG. 3 illustrates forming the multi-layer PCB 10 only on the platform 560, in some variations the 3D printing system 50 forms the multi-layer PCB 10 on one or more power device—substrate assemblies 20 as described below. For example, the platform 560 can include pockets for holding one or more power device—substrate assemblies 20 while the multi-layer PCB 10 is 3D printed thereon.

Referring now to FIGS. 4A-4F, steps for manufacturing a highly integrated power electronics embedded PCB—cold plate assembly 2 according to at least one form of the present disclosure are shown. For example, FIG. 4A illustrates two cold plate substrates 410 to be bonded to a first side 201 of two power device—substrate assemblies 20 and FIG. 4B illustrates the two cold plate substrates 410 bonded to the first side 201 of the two power device—substrate assemblies 20 to form a pair of power device—cold plate substrates assemblies 30. It should be understood that the first side 201 includes a surface (e.g., a planar surface) and the two cold plate substrates 410 each include a complimentary surface (e.g., a planar surface) such that the two power device—substrate assemblies 20 and the cold plate substrates 410 can be and are bonded to each other using known semiconductor and/or electronic industry bonding techniques such a soldering, liquid phase transition bonding, and laminating, among others. And in some variations, a bonding interface 401 is disposed between a cold plate substrate 410 and a first side 201 of a respective power device—substrate assembly 20. That is, in some variations a cold plate substrate 410 is bonded to a power device—substrate assembly 20 via a bonding interface 401.

In some variations, the bonding interface 401 includes a LTR dielectric layer disposed between the first side 201 and a respective cold plate substrate 410. In other variations, the bonding interface 401 includes a CVD dielectric layer disposed between the first side 201 of a respective substrate 202 and the cold plate substrate 410. In still other variations, the bonding interface 401 includes a ceramic sintered layer disposed between the first side 201 of a respective substrate 202 and the cold plate substrate 410. And in at least one variation the bonding interface 401 is one or more 3D printed layers disposed between the first side 201 and the cold plate substrate 410. As used herein, the phrase “CVD dielectric layer” refers to a dielectric layer that has been formed on a surface using chemical vapor deposition (CVD). In addition, and as discussed above, in at least one variation fins, porous material, mesh-structured, machined and/or cast heat sinks 412 are bonded to or integral with the cold plate substrate 410.

Referring particularly to FIGS. 4C-4D, a multi-layer PCB 10 to be bonded to a second side 203 of the two power device—substrate assemblies 20 is shown in FIG. 4C and the lower surface 102 of the multi-layer PCB 10 bonded to the two power device—substrate assemblies 20 is shown in FIG. 4D. In some variations, and as illustrated in FIG. 4C, the second side 203 of a power device—substrate assembly 20 is oppositely disposed from the first side 201. And while not shown in FIG. 4D, in some variations a bonding interface is disposed between the second sides 203 of the two power device—substrate assemblies 20 and the lower surface 102 of the multi-layer PCB 10. That is, in some variations the multi-layer PCB 10 is bonded to the two power device—substrate assemblies 20 via a bonding interface (not shown).

Similar to the first side 201, it should be understood that the second side 203 includes a surface (e.g., a planar surface) that is complimentary with the lower surface 102 of the multi-layer PCB 10 such that the multi-layer PCB 10 and the two power device—substrate assemblies 20 can be and are bonded to each other using known semiconductor and/or electronic industry bonding techniques such a soldering, liquid phase transition bonding, and laminating, among others. In some variations, the second side 203 includes an upper (+z direction) surface of the power devices 200. That is, an upper surface of the power devices 200 form a portion of the second side 203 of the power device—substrate assemblies 20 as shown in FIG. 4C. And in such variations, the upper surfaces of the power devices 200 can be bonded to the lower surface 102 of the multi-layer PCB 10.

Referring to FIG. 4E, a cold plate manifold 420 disposed on the multi-layer PCB 10 with the power device—cold plate substrates assemblies 30 embedded therein is shown. It should be understood that the cold plate manifold 420 in combination with the cold plate substrate 410 form two fluid chambers 400 configured for a cooling fluid (not shown) to flow therethrough. In addition, the cold plate manifold 420 includes an inlet 44 and an outlet 46 in fluid communication with the two fluid chambers 400. In some variations, the cold plate manifold 420 is a 3D printed cold plate manifold, and in at least one variation the cold plate manifold 420 is a 3D printed polymer cold plate manifold. Also, the cold plate manifold 420 can be bonded to the lower surface 102 of the multi-layer PCB 10, and optionally to at least a portion of the power device—cold plate substrates assemblies 30, using any bonding technique, bonding process, and/or bonding material suitable for bonding two IPEs embedded PCB components together, illustratively including but not limited to solder, adhesives, among others. In at least one variation, the cold plate manifold 420 is attached and/or bonded to the lower surface 102 using an epoxy, e.g., a soft epoxy.

In some variations, and with reference to FIG. 4F, bonding or attachment of the cold plate manifold 420 to the multi-layer PCB 10 is enhanced with mechanical fasteners. For example, threaded bolts or screws 49 can extend through the cold plate manifold 420 and engage threaded lugs 492 embedded in the multi-layer PCB 10 such that a compressive force between the cold plate manifold 420 and the multi-layer PCB 10 is provided and the fluid chambers 400 are “leak tight.” That is, fluid enters and exits the fluid chambers 400 only via the inlet 440 and the outlet 460. In addition, it should be understood that the threaded bolts or screws 49 in combination with the threaded lugs 492 can provide reinforcement, e.g., rigidity, to the cold plate manifold 420. And in at least one variation, an inlet tube 450 and an outlet tube 470 to be attached to and in fluid communication with the inlet 440 and outlet 460, respectively, is shown in FIG. 4F, such that, in combination with the mechanical fasteners, the highly IPEs embedded PCB—cold plate assembly 2 shown in FIG. 1 is formed.

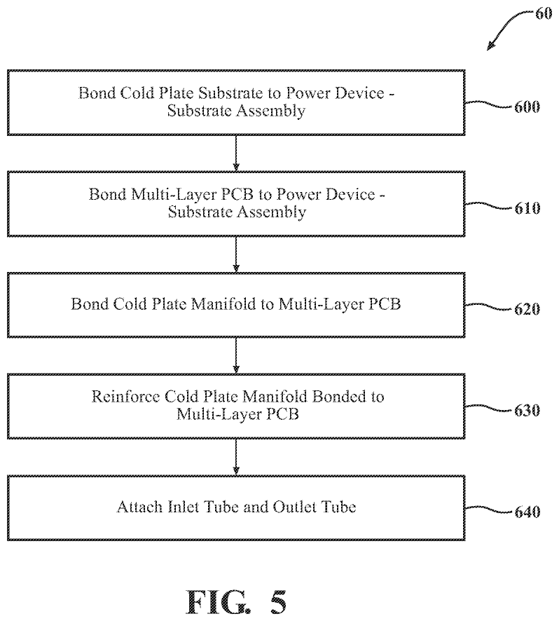

Referring now to FIG. 5, a method 60 for manufacturing a highly IPEs embedded PCB—cold plate assembly includes bonding a cold plate substrate to a first side of a power device—substrate assembly at 600 and bonding a multi-layer PCB onto a second side of the power device—substrate assembly at 610. And at 620, a cold plate manifold is bonded to the multi-layer PCB such that, in combination with the cold plate substrate, a fluid chamber is formed within the cold plate manifold. In some variations, bonding of the cold plate manifold to the multi-layer PCB and/or reinforcement of the cold plate manifold is enhanced at 630 and an inlet tube and/or outlet tube are/is attached to an inlet and/or outlet of the cold plate manifold at 640.

The preceding description is merely illustrative in nature and is in no way intended to limit the disclosure, its application, or its uses. Work of the presently named inventors, to the extent it may be described in the background section, as well as aspects of the description that may not otherwise qualify as prior art at the time of filing, are neither expressly nor impliedly admitted as prior art against the present technology.

The block diagram in the figures illustrates the functionality and operation of possible implementations of methods and systems according to various forms or variations. In this regard, each block in the block diagram may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

As used herein, the phrase at least one of A, B, and C should be construed to mean a logical (A or B or C), using a non-exclusive logical “or.” It should be understood that the various steps within a method may be executed in different order without altering the principles of the present disclosure. Disclosure of ranges includes disclosure of all ranges and subdivided ranges within the entire range.

The headings (such as “Background” and “Summary”) and sub-headings used herein are intended only for the general organization of topics within the present disclosure and are not intended to limit the disclosure of the technology or any aspect thereof. The recitation of multiple variations or forms having stated features is not intended to exclude other variations or forms having additional features, or other variations or forms incorporating different combinations of the stated features.

As used herein the term “about” when related to numerical values herein refers to known commercial and/or experimental measurement variations or tolerances for the referenced quantity. In some variations, such known commercial and/or experimental measurement tolerances are +/−10% of the measured value, while in other variations such known commercial and/or experimental measurement tolerances are +/−5% of the measured value, while in still other variations such known commercial and/or experimental measurement tolerances are +/−2.5% of the measured value. And in at least one variation, such known commercial and/or experimental measurement tolerances are +/−1% of the measured value.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that a form or variation can or may comprise certain elements or features does not exclude other forms or variations of the present technology that do not contain those elements or features.

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one variation, or various variations means that a particular feature, structure, or characteristic described in connection with a form or variation or particular system is included in at least one variation or form. The appearances of the phrase “in one variation” (or variations thereof) are not necessarily referring to the same variation or form. It should also be understood that the various method steps discussed herein do not have to be conducted in the same order as depicted, and not each method step is required in each variation or form.

The foregoing description of the forms and variations has been provided for purposes of illustration and description. It is not intended to be exhaustive or to limit the disclosure. Individual elements or features of a particular form or variation are generally not limited to that particular form or variation, but, where applicable, are interchangeable and can be used in a selected form or variation, even if not specifically shown or described. The same may also be varied in many ways. Such variations should not be regarded as a departure from the disclosure, and all such modifications are intended to be included within the scope of the disclosure.

What is claimed is:

1. A method comprising:
bonding a cold plate substrate onto a first side of a power device—substrate assembly;
bonding a multi-layer printed circuit board (PCB) onto a second side of the power device—substrate assembly; and
bonding a cold plate manifold onto the multi-layer PCB and forming a cold plate and a high integrated power electronics embedded PCB—cold plate assembly with the cold plate.

2. The method according to claim 1, wherein the cold plate substrate comprises fins, porous material, mesh-structured, machined and/or cast heat sinks.

3. The method according to claim 1, wherein the cold plate substrate comprises a bonding substrate bonded to the first side of the power device—substrate assembly and fins, porous material, mesh-structured, machined and/or cast heat sinks bonded to or integral with the bonding substrate.

4. The method according to claim 3, wherein the cold plate comprises a fluid chamber with fins, porous material, mesh-structured, machined and/or cast heat sinks disposed in the fluid chamber.

5. The method according to claim 4, wherein the cold plate comprises an inlet configured for a cooling fluid to flow into the fluid chamber and an outlet configured for the cooling fluid to flow out of the fluid chamber.

6. The method according to claim 5 further comprising attaching an inlet tube to the inlet and an outlet tube to the outlet.

7. The method according to claim 1, wherein the second side of the power device—substrate assembly is oppositely disposed from the first side of the power device—substrate assembly.

8. The method according to claim 1, wherein the multi-layer PCB is bonded to the second side of the second side of the power device—substrate assembly by 3D printing the multi-layer PCB onto the second side of the power device—substrate assembly.

9. The method according to claim 1, wherein the cold plate manifold is epoxy bonded to the multi-layer PCB.

10. The method according to claim 1, wherein the cold plate manifold is a 3D printed polymer cold plate manifold.

11. The method according to claim 10, wherein the 3D printed polymer cold plate manifold is epoxy bonded to the multi-layer PCB.

12. The method according to claim 11 further comprising installing a plurality of mechanical fasteners to reinforce the cold plate manifold epoxy bonded to the multi-layer PCB.

13. The method according to claim 12, wherein the plurality of mechanical fasteners extend through the cold plate manifold and engage the multi-layer PCB.

14. The method according to claim 13, wherein the multi-layer PCB comprises a plurality of embedded lugs and the plurality of mechanical fasteners engage the plurality of embedded lugs.

15. The method according to claim 1, wherein:
bonding the cold plate substrate onto the first side of the power device—substrate assembly comprises bonding a plurality of cold plate substrates onto the first side of a plurality of power device—substrate assemblies; and
bonding the cold plate manifold onto the multi-layer PCB forms a plurality of fluid chambers and the high integrated power electronics embedded PCB—cold plate assembly comprises the plurality of fluid chambers.

16. A method comprising:
bonding a cold plate substrate onto a first side of a power device—substrate assembly;
3D printing a multi-layer printed circuit board (PCB) onto a second side of the power device—substrate assembly;
bonding a cold plate manifold onto the multi-layer PCB and forming a cold plate; and
installing a plurality of mechanical fasteners to reinforce the cold plate manifold bonded to the multi-layer PCB.

17. The method according to claim 16, wherein the plurality of mechanical fasteners extend through the cold plate manifold and engage the multi-layer PCB.

18. The method according to claim 17, wherein the multi-layer PCB comprises a plurality of embedded lugs and the plurality of mechanical fasteners engage the plurality of embedded lugs.

19. A method comprising:
bonding a cold plate substrate onto a first side of a power device—substrate assembly;
3D printing a multi-layer printed circuit board (PCB) onto a second side of the power device—substrate assembly;
bonding a polymer cold plate manifold onto the multi-layer PCB and forming, in combination with the cold plate substrate, a cold plate; and
installing a plurality of mechanical fasteners to reinforce the polymer cold plate manifold bonded to the multi-layer PCB.

20. The method according to claim 19. wherein the cold plate comprises a fluid chamber with fins, porous material, mesh-structured, machined and/or cast heat sinks disposed in the fluid chamber.
